(19) United States
(12) Patent Application Publication
(10) Pub. No.: US 2005/0278611 A1
(43) Pub. Date: Dec. 15, 2005

(54) High-speed turbo decoding apparatus and method thereof

(76) Inventors: Sung-Jin Park, Seoul (KR); Min-Goo Kim, Yongin-si (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 11/135,632

(22) Filed: May 24, 2005

(30) Foreign Application Priority Data
May 24, 2004 (KR) 2004-36741

(51) Int. Cl. H03M 13/00; H03M 13/03

(52) U.S. Cl. 714/792

(57) ABSTRACT

A turbo decoding apparatus and method for decoding using a trellis structure comprising a plurality of states and paths between the states in a high-speed packet data communication system are provided. The apparatus and method comprise a plurality of delta metric blocks for calculating a delta metric indicating a transition probability for paths from each state to another state according to an input data bit; an alpha metric block for normalizing the delta metric, and calculating an alpha metric indicating a forward state transition probability for each of the states using the normalized delta metric; at least one beta metric block for normalizing the delta metric, and calculating a beta metric indicating a reverse state transition probability for each of the states using the normalized delta metric; and a log likelihood ratio (LLR) block for receiving the alpha metric and the beta metric and calculating LLR values for symbols of a final state using the received alpha metric and beta metric.

### PRIORITY

This application claims the benefit under 35 U.S.C. § 119(a) of an application entitled “High-Speed Turbo Decoding Apparatus” filed in the Korean Intellectual Property Office on May 24, 2004 and assigned Serial No. 2004-36741, the entire contents of which are incorporated herein by reference.

### BACKGROUND OF THE INVENTION

1. Field of the Invention

The present invention relates generally to decoding in a mobile communication system. In particular, the present invention relates to a turbo decoding apparatus and method to which a window with a variable size is applied.

2. Description of the Related Art

In digital communication systems, forward error correction (FEC) codes are generally used to increase reliability of data transmission by effectively correcting possible errors occurring in channels during the data transmission. The typical example of the FEC codes is turbo codes. Turbo codes, due to their superiority over convolutional codes in error correcting capability during high-speed data transmission, have been adopted for both a synchronous Code Division Multiple Access 2000 (CDMA2000) system and an asynchronous Universal Mobile Telecommunication System (UMTS) system, both of which are attracting public attention as 3^{rd} generation (3G) mobile communication systems. Because both the synchronous system and the asynchronous system enable high-speed packet data communication, a high-speed turbo decoder performs well in these systems. In 1× Evolution Data and Voice (1×EV-DV) defined in a CDMA standard, it is provided that various code rates should be applied to a turbo decoder.

FIG. 1 is a diagram illustrating a structure of a general turbo decoding apparatus. As illustrated, a turbo decoder 200 comprises a Soft-In Soft-Output (SISO) constituent decoder, by way of example. The turbo decoder can also be implemented with a Maximum A Posterior (MAP) scheme or a Register Exchange Soft Output Viterbi Algorithm (RESOVA) scheme instead of the SISO scheme. The SISO scheme calculates a probability depending on the reliability of symbols, and the RESOVA scheme calculates a probability for a codeword by considering a path through which symbols pass as a long codeword.

Referring to FIG. 1, symbols (data bits) stored in a memory buffer 100 are provided to an input terminal of the turbo decoder 200. Deinterleaved bits are stored in the memory buffer 100 after being classified into a systematic code and parity codes (a parity #1 code and a parity #2 code) which are non-systematic codes. The memory buffer 100 simultaneously provides bits for the systematic code and bits for the parity codes to the turbo decoder 200. Because the memory buffer 100 outputs all of the 3 codes of the system code and the non-systematic codes, the codes output from the memory buffer 100 are provided to a multiplexer (MUX) 210 in the turbo decoder 200 through 3 buses.

The turbo decoder 200 includes the multiplexer 210, the constituent decoder 220 to which a SISO algorithm is applied (hereinafter referred to as a “SISO decoder”), an interleaver 230, a deinterleaver 240, an output buffer 250, and a Cyclic Redundancy Code (CRC) checker 260.

The SISO decoder 220 performs SISO decoding on an output of the multiplexer 210 using the structures illustrated in FIGS. 2A and 2B. The interleaver 230 interleaves an output of the SISO decoder 220, and the deinterleaver 240 deinterleaves the output of the SISO decoder 220. The output buffer 250 stores the result deinterleaved by the deinterleaver 240 so that it can communicate with a Layer 1 (L1) processor 270. The CRC checker 260 performs a CRC check on the deinterleaving result by the deinterleaver 240, and provides the result to the L1 processor 270.

The SISO decoder 220 performs an operation of calculating several metrics in a decoding process. Specifically, in the decoding operation of the SISO decoder 220, a delta metric value, an alpha (α) metric value, a beta (β) metric value, and a log likelihood ratio (LLR) value are calculated.

The delta metric, also known as a branch metric, indicates a transition probability of paths from one state to another state in a coding trellis structure. The alpha metric, also known as a forward state metric, indicates an accumulated transition probability from a previous state to the current state. The beta metric indicates an accumulated transition probability from the next state to the current state. After the alpha metric and the beta metric are both calculated, a LLR value is calculated. The LLR value indicates a probability for a symbol, and expresses a ratio of a probability that the symbol will become ‘1’ to a probability that the symbol will become ‘0’, in a log scale.

Generally, because a frame mode decoder requires an alpha metric and a beta metric to calculate an LLR value, the frame mode decoder sequentially calculates the alpha metrics and the LLR values after fully calculating the beta metrics, thus causing a time delay during calculation of the beta metrics.

FIGS. 2A and 2B are diagrams illustrating a metric calculation order by a general SISO decoder. Specifically, FIG. 2A illustrates a process of calculating the alpha metrics and FIG. 2B illustrates a process of calculating the beta metrics.

Referring to FIGS. 2A and 2B, it is noted that there is a difference between an operation of calculating the alpha metrics and an operation of calculating the beta metrics. An alpha metric αₖ of a k^{th} state is calculated from an alpha metric of a (k−1)^{th} state, which is a previous value. A beta metric βₖ of a k^{th} state is calculated from a beta metric of a (k+1)^{th} state, which is a next value. In this manner, received signals should be consulted in their reverse reception order to calculate the beta metrics, causing an initial delay that corresponds to the full length of the received signals.

In order to solve the foregoing problem, a sliding window mode is applied, for outputting consecutive beta metrics using 2 beta metric blocks. In the sliding window mode, a signal received for beta metric calculation is sliced in a predetermined length before being calculated. If beta metrics are calculated using the received signal sliced in a predetermined length, incorrect probabilities are calculated for the initial values but correct probabilities are calculated for the later values. The values in a period for which the correct probabilities are calculated are used for actual LLR calculation. Therefore, the sliding window mode scheme distinguishes an incorrect period from a reliable period so that the window mode can be used. That is, a beta metric calculation block is designed such that while a correct period is calculated in one window, an incorrect period is calculated in another window, and then the calculation results are combined (or interlaced) with each other.

As described above, the general SISO decoder comprises delta, alpha and beta blocks for metric calculation, and a LLR block that performs decoding based on probabilities and outputs the decoding result.

FIG. 3 is a diagram illustrating a structure of a general SISO decoder. For example, in this drawing, the SISO decoder 220 is implemented with a sliding window mode scheme. Herein, a beta block comprises 2 beta metric blocks according to the number of windows.

Referring to FIG. 3, a demultiplexer (DEMUX) 221 accesses data bits stored in the memory buffer 100 at a predetermined rate, for example, 3 times the rate of a clock (operating frequency) for the turbo decoder 200, and provides a first output, a second output and a third output. Three delta metric blocks 223a, 223b and 223c calculate delta metrics for the first output, the second output and the third output, respectively. An alpha metric 225 receives a delta metric calculated by the delta metric block 223a, and calculates an alpha metric corresponding thereto. A beta block 227 includes a first delta metric block 227a for calculating a first delta metric of a correct period in one window, a second beta metric block 227b for calculating a second beta metric in the remaining period of the window, and a multiplexer 227c for multiplexing the calculation results by the blocks 227a and 227b.

A LLR block 229 receives the alpha metric calculated by the alpha metric block 225 and the multiplexing result by the multiplexer 227c, calculates LLR values corresponding thereto, and determines symbols based on the LLR values. The determined symbols from the LLR block 229 are output to the interleaver 230 and the deinterleaver 240, shown in FIG. 1, for the next interleaving/deinterleaving.

The LLR block 229 for calculating LLR values calculates probabilities for symbols based on forward and reverse state transition probabilities. If the LLR value is a positive number, it represents a symbol of ‘1’, and if the LLR value is a negative number, it represents a symbol of ‘0’.

In order to decode received signals in this manner, the SISO decoder 220 calculates both the alpha metric value and the beta metric value. It should be noted herein that because the beta metric values should be calculated in the reverse order of the received signals stored in the memory buffer 100, the LLR values cannot be calculated until calculation of the beta metrics is fully completed.

The mobile communication system used before the CDMA2000 1×EV-DV standard has been proposed does not support high-speed packet data transmission. In this case, therefore, a decoder having a decoding capability of several hundreds of Kbps was enough. However, in a mobile communication system that requires a decoding capability of several Mbps, such as the 1×EV-DV system and the UMTS system, a high-speed decoder having an operating speed corresponding thereto is required.

An operating speed of a turbo decoder is determined based on a critical delay of the MAP or SISO decoder, which is its basic decoder. That is, if the MAP decoder or SISO decoder is designed to operate at high speeds, the turbo decoder can also operate at high speeds. Accordingly, there is a need to reduce an operation delay of the general MAP or SISO decoder and increase a decoding speed.

### SUMMARY OF THE INVENTION

It is, therefore, an object of the present invention to provide an apparatus and method for enabling high-speed decoding by improving a basic structure of a constituent decoder in a turbo decoding apparatus.

It is another object of the present invention to provide a decoder and method for increasing a calculation speed of alpha and beta metrics.

It is further another object of the present invention to provide a decoder including a log likelihood ratio (LLR) block having a multi-stage pipeline structure and a method for using the same.

According to one aspect of the present invention, there is provided a turbo decoding apparatus and method for decoding using a trellis structure comprised of a plurality of states and paths between the states in a high-speed packet data communication system. The apparatus and method comprise a plurality of delta metric blocks for calculating a delta metric for indicating a transition probability for paths from each state to another state according to an input data bit; an alpha metric block for normalizing the delta metric, and calculating an alpha metric indicating a forward state transition probability for each of the states using the normalized delta metric; at least one beta metric block for normalizing the delta metric, and calculating a beta metric indicating a reverse state transition probability for each of the states using the normalized delta metric; and a log likelihood ratio (LLR) block for receiving the alpha metric and the beta metric and calculating LLR values for symbols of a final state using the received alpha metric and beta metric.

According to one aspect of the present invention, there is provided a turbo decoding apparatus and method for decoding using a trellis structure comprised of a plurality of states and paths between the states in a high-speed packet data communication system. The apparatus and method comprise a plurality of delta metric blocks for calculating a delta metric for indicating a transition probability for paths from each state to another state according to an input data bit; an alpha metric block for calculating an alpha metric by receiving the delta metric, and performing bit normalization by reversing a most significant bit (MBS) excluding a sign bit of the alpha metric if the alpha metric values exceed a predetermined bit width; a beta metric block for calculating a beta metric by receiving the delta metric, and performing bit normalization by reversing a MBS bit excluding a sign bit of the beta metric if the beta metric values exceed a predetermined bit width; and a log likelihood ratio (LLR) block comprising two buffers for receiving the bit-normalized alpha and beta metric values and storing intermediate calculation values for calculating LLR values for symbols of a final state.

### BRIEF DESCRIPTION OF THE DRAWINGS

The above and other objects, features and advantages of the present invention will become more apparent from the following detailed description when taken in conjunction with the accompanying drawings in which:

FIG. 1 is a diagram illustrating a structure of a general turbo decoding apparatus;

FIG. 2A is a diagram illustrating a process of calculating alpha metrics using a general Soft-In Soft-Output (SISO) decoder;

FIG. 2B is a diagram illustrating a process of calculating beta metrics using a general SISO decoder;

FIG. 3 is a diagram illustrating a structure of a general SISO decoder;

FIG. 4 is a diagram illustrating a general delta metric block;

FIG. 5A is a diagram illustrating a detailed structure of a general alpha metric block;

FIG. 5B is a diagram illustrating a detailed structure of the general alpha metric calculation block illustrated in FIG. 5A;

FIG. 6A is a diagram illustrating a detailed structure of a general beta metric block;

FIG. 6B is a diagram illustrating a detailed structure of the general beta metric calculation block illustrated in FIG. 6A;

FIG. 7 is a diagram illustrating a detailed structure of the general maximum value calculation block illustrated in FIGS. 5B and 6B;

FIG. 8 is a diagram illustrating a detailed structure of a general log likelihood ratio for (LLR) block;

FIG. 9 is a diagram illustrating bit normalization for underflow according to an embodiment of the present invention;

FIG. 10 is a diagram illustrating a detailed structure of an alpha metric calculation block to which bit normalization is applied according to an embodiment of the present invention;

FIG. 11 is a diagram illustrating a detailed structure of an LLR block according to an embodiment of the present invention;

FIG. 12 is a diagram illustrating an example of a normalization operation according to an embodiment of the present invention;

FIG. 13A is a diagram illustrating a structure of an alpha metric block according to an embodiment of the present invention;

FIG. 13B is a diagram illustrating a detailed structure of an alpha metric calculation block according to an embodiment of the present invention;

FIG. 14A is a diagram illustrating a structure of a beta metric block according to an embodiment of the present invention; and

FIG. 14B is a diagram illustrating a detailed structure of a beta metric calculation block according to an embodiment of the present invention.

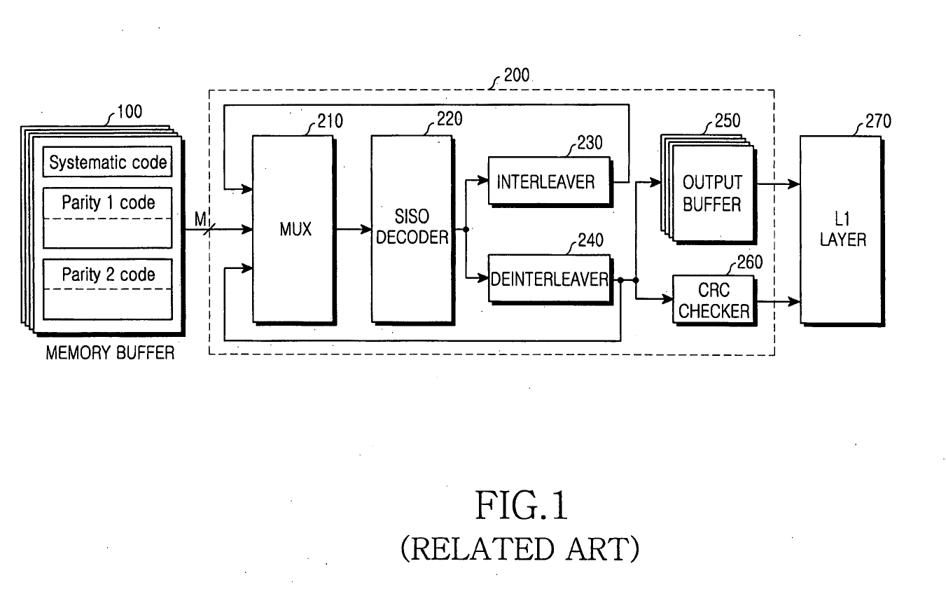

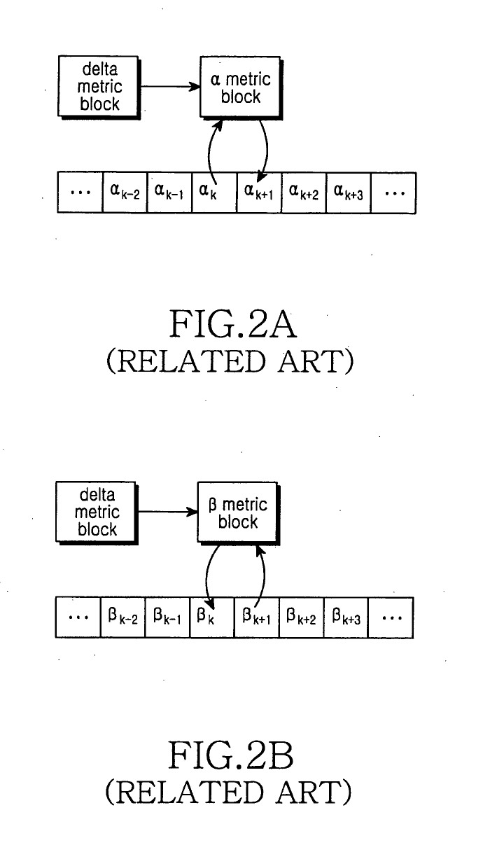

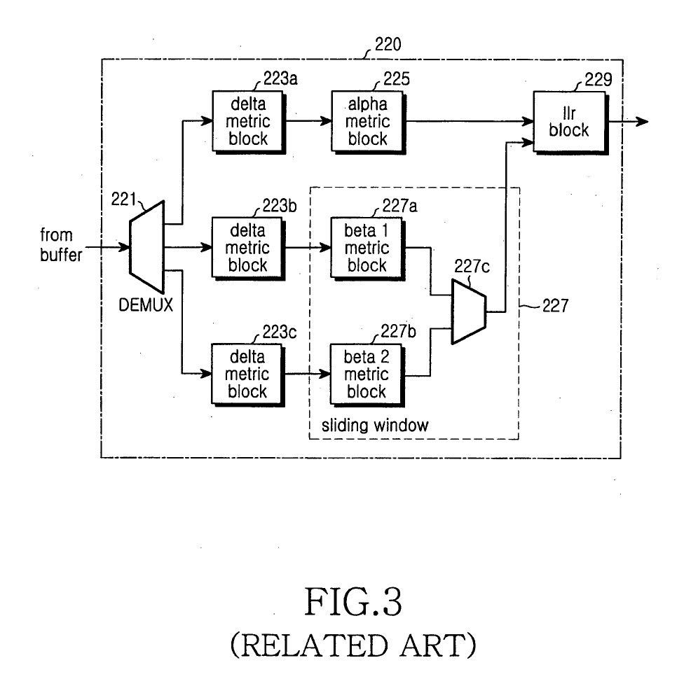

Throughout the drawings, the same or similar elements are denoted by the same reference numerals.

### DETAILED DESCRIPTION OF EXEMPLARY EMBODIMENTS

Several embodiments of the present invention will now be described in detail with reference to the accompanying drawings. In the following description, a detailed description of known functions and configurations incorporated herein has been omitted for conciseness.

The embodiments of the present invention reduce a delay and thus increase a decoding speed by improving a structure of a normalization block of a constituent decoder in a turbo decoder.

Before a detailed description of the present invention is given, a description will be made of a basic structure and a calculation diagram for a delta metric block, an alpha metric block and a beta metric block, which are elements of a general Soft-In Soft-Output/Maximum A Posterior (SISO/MAP) decoder.

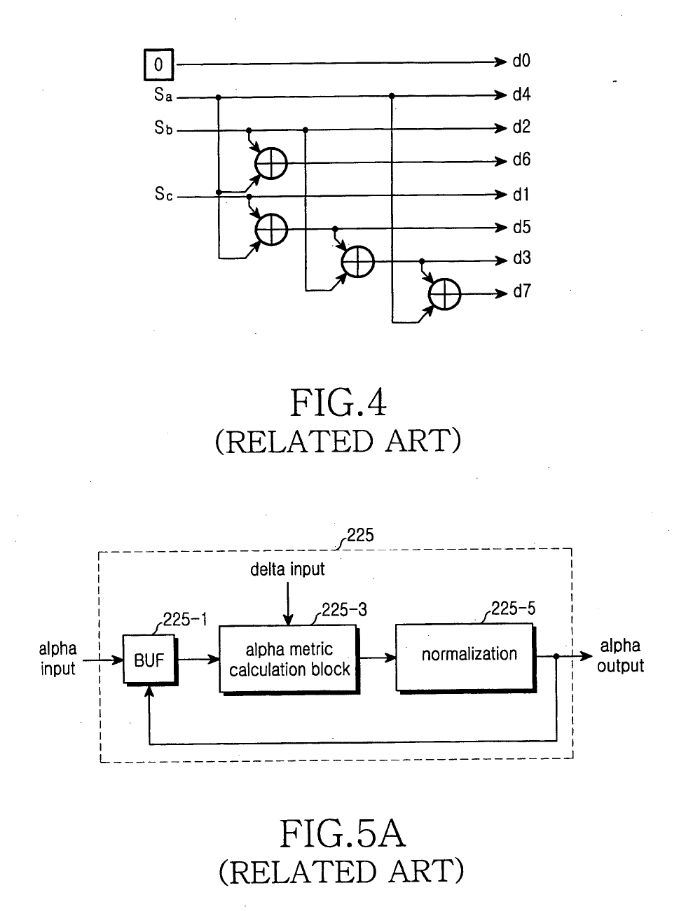

FIG. 4 is a diagram illustrating a general delta metric block. Referring to FIG. 4, a delta metric block 223 receives 4 signals 0, Sₐ, S_{b} and S_{c}, and outputs 8 resultant signals d0 to d7 by calculating the 4 received signals. The output signals d0, d4, d2 and d1 are equal to the input signals 0, Sₐ, S_{b} and S_{c}, respectively. The output signal d6 is an exclusive-OR (XOR) operation result for the input signals Sₐ and S_{b}, and the output signal d5 is an XOR operation result for the input signals Sₐ and S_{c}. The output signal d3 is an XOR operation result for the input signal S_{b} and the output signal d5. Finally, the output signal d7 is an XOR operation result for the input signal Sₐ and the output signal d3.

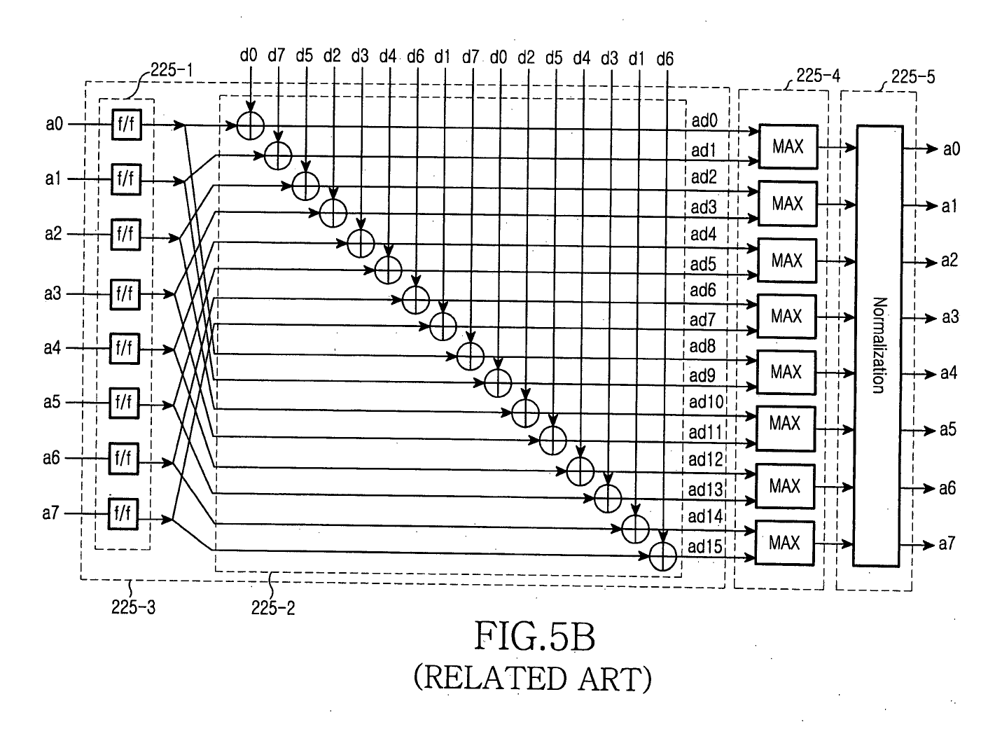

FIG. 5A is a diagram illustrating a detailed structure of a general alpha metric block. Referring to FIG. 5A, an alpha metric block 225 comprises a memory buffer (BUF) 225-1 for storing initial state values used for performing recursive alpha metric calculation, an alpha metric calculation block 225-3 for calculating alpha metrics, and a normalization block 225-5 for preventing overflow/underflow of output values of the alpha metric calculation block 225-3.

FIG. 5B is a diagram illustrating a detailed structure of the alpha metric calculation block illustrated in FIG. 5A. Referring to FIG. 5B, a memory buffer 225-1 comprises flip-flops for receiving and storing alpha input values a0 to a7 for initial state setting. The alpha input values are predetermined initial values at the initial stage, and thereafter, are alpha metric values of the previous state. A calculation block 225-2 performs XOR operations on previous alpha metric input values a0 to a7 output from the flip-flops and delta metrics d0 to d7 output from a delta metric block 225-3. A maximum value calculation block 225-4 compares the result values ad0 to ad15 of the calculation block 225-2 in pairs to select greater values, and provides the selected values to a normalization block 225-5. The normalization block 225-5 normalizes the selected values and outputs the normalized values as alpha metric values. The output alpha metric values are stored in the memory buffer 225-1 to be used as alpha metric input values for calculating the next alpha metrics.

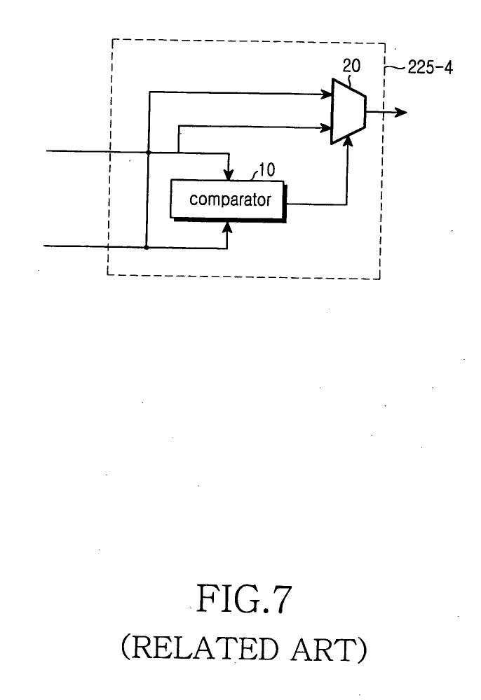

For example, if initial input values a0 and a1 are output from the memory buffer 225-1, XOR results ad0 and ad1 between the initial input values a0 and a1 and the current-state metrics d0 and d7 are input to the maximum value calculation block 225-4. The maximum value calculation block 225-4 compares the ad0 with the ad1, and selects the greater value. A detailed structure of the maximum value calculation block 225-4 will be described later with reference to FIG. 7. The selected value is normalized in the normalization block 225-5, and stored in a first flip-flop as a0. The a0 is used as an input value for calculating the next alpha metric value, and the input value a0 is logically XORed again with the d7 value. The XOR result ad8 between the a0 and the d7 is normalized again passing through the maximum value calculation block 225-4 and the normalization block 225-5, and output as a4. The a4 is again used as an alpha input value.

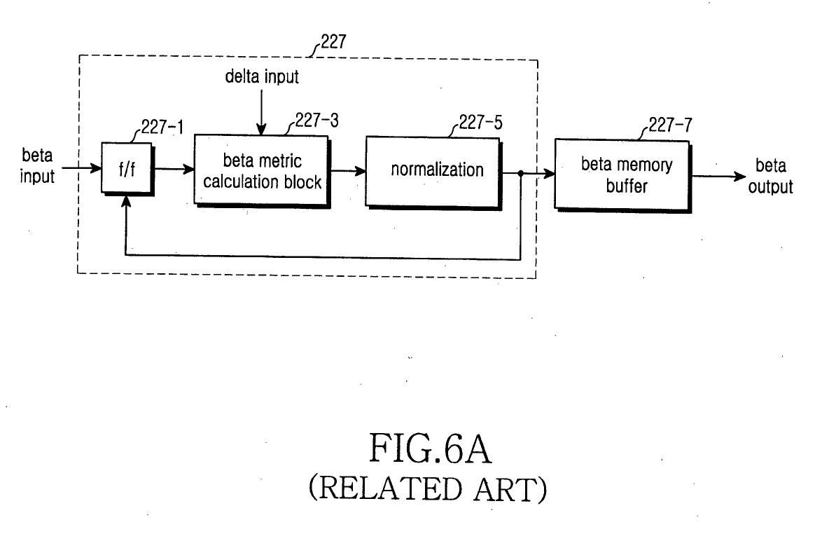

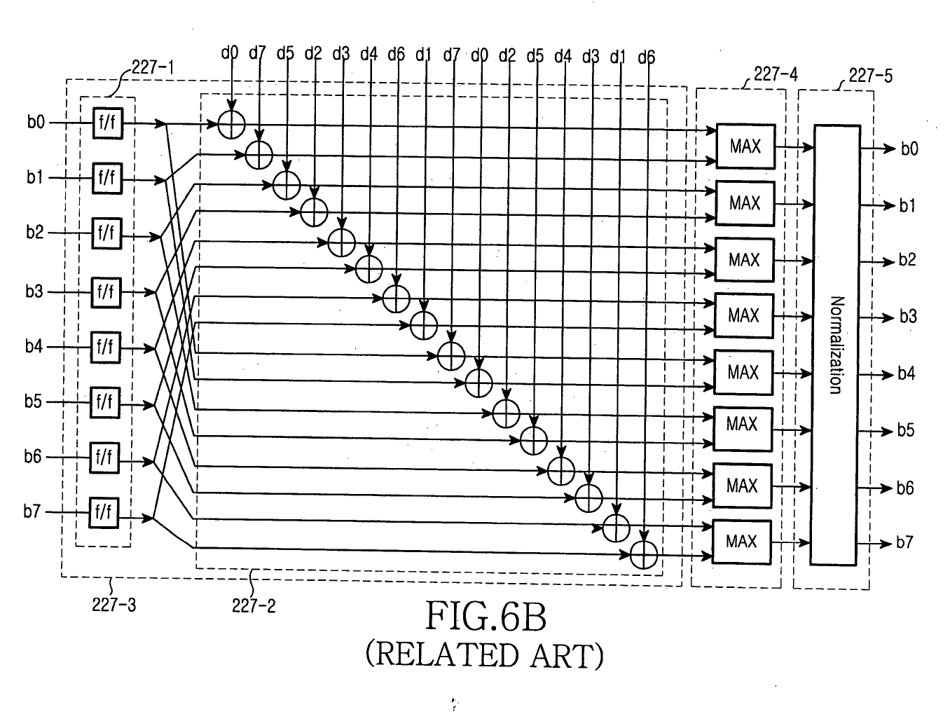

FIG. 6A is a diagram illustrating a detailed structure of a general beta metric block. Referring to FIG. 6, a beta metric block 227 comprises a memory buffer 227-1 for storing initial values used for performing recursive calculations on signals received in the reverse order, a beta metric calculation block 227-3 for calculating beta metrics, and a normalization block 227-5 for preventing overflow/underflow of output values of the beta metric calculation block 227-3. The beta memory buffer 227-7 stores the beta metric values output from the normalization block 227-5, and outputs the beta metric values in the reverse order for the next beta metric calculation.

FIG. 6B is a diagram illustrating a detailed structure of the beta metric calculation block 227-3 illustrated in FIG. 6A. Referring to FIG. 6B, a memory buffer 227-1 comprises flip-flops for storing beta input values b0 to b7. The beta input values are predetermined initial values at the initial stage, and thereafter, are beta metric values of the next state. A calculation block 227-2 performs XOR operations on beta metric input values b0 to b7 output from the flip-flops and delta metrics d0 to d7 output from a delta metric block 227-3. A maximum value calculation block 227-4 compares the result values of the calculation block 227-2 in pairs to select greater values, and provides the selected values to a normalization block 227-5. The normalization block 227-5 normalizes the selected values and outputs the normalized values as beta metric values. The output beta metric values are used as beta metric input values for calculating the next beta metrics.

For example, if initial input values b0 and b1 are output from the memory buffer 227-1, XOR results between the initial input values b0 and b1 and the current-state metrics d0 and d7 are input to the maximum value calculation block 227-4. The maximum value calculation block 227-4 compares the result values with each other, and selects the greater value. A detailed structure of the maximum value calculation block 227-4 will be described later with reference to FIG. 7. The selected value is normalized in the normalization block 227-5, and output as b0. The b0, together with b1, is used as an input value for calculating the next beta metric value, and the input values b0 and b1 are logically XORed again with the d7 and d0 values. The maximum value calculation block 227-4 compares again the XOR results between the b0 and b1 values and the d0 and d7 values to select the greater value. The selected value is normalized in the normalization block 227-5, and output as b4. The b4 is stored again in the memory buffer 227-1 to be used as the beta input values b2 and b6.

FIG. 7 is a diagram illustrating a detailed structure of the maximum value calculation block illustrated in FIGS. 5B and 6B. Referring to FIG. 7, a maximum value calculation block 225-4 (or 227-4) comprises a comparator 10 for comparing two input values among XOR results between alpha or beta metric input values and delta metric input values, and a multiplexer 20 for selecting a greater value between the two input values according to the comparison result of the comparator 10. The maximum value calculation block 225-4 outputs the result value selected by the multiplexer 20. The result value is input to the normalization block 225-5 in the alpha metric block 225 or the normalization block 227-5 in the beta metric block 227.

With reference to FIGS. 4 to 7, a description will now be made of delays occurring through the delta metric block, the alpha metric block and the beta metric block.

Referring to FIG. 4, because d7 is an XOR result between Sₐ and d3, and the d3 is an XOR result between S_{b} and d5, the maximum delay occurring in the delta metric block 223 becomes two times the XOR operation time as follows.
Delay of delta block=adder+adder

Referring to FIGS. 5B and 7, a delay in the alpha metric block 225 is the sum of delays occurring in the calculation block 225-2 for performing XOR operations on alpha metric input values and delta metric input values, the comparator 10 and the multiplexer 20 in the maximum value calculation block 225-4, the normalization block 225-5, and the memory buffer 225-1 for storing initial values or alpha metric values, as follows.
Delay of alpha block=adder+comparator+MUX+normalization+flip-flop

Referring to FIGS. 6B and 7, a delay in the beta metric block 227 is the sum of delays occurring in the calculation block 227-2 for performing XOR operations on beta metric input values and current-state metric values, the comparator 10 and the multiplexer 20 in the maximum value calculation block 227-4, the normalization block 227-5, and the memory buffer 227-1 for storing beta metric values, as follows.
Delay of beta block=adder+comparator+MUX+normalization+flip-flop

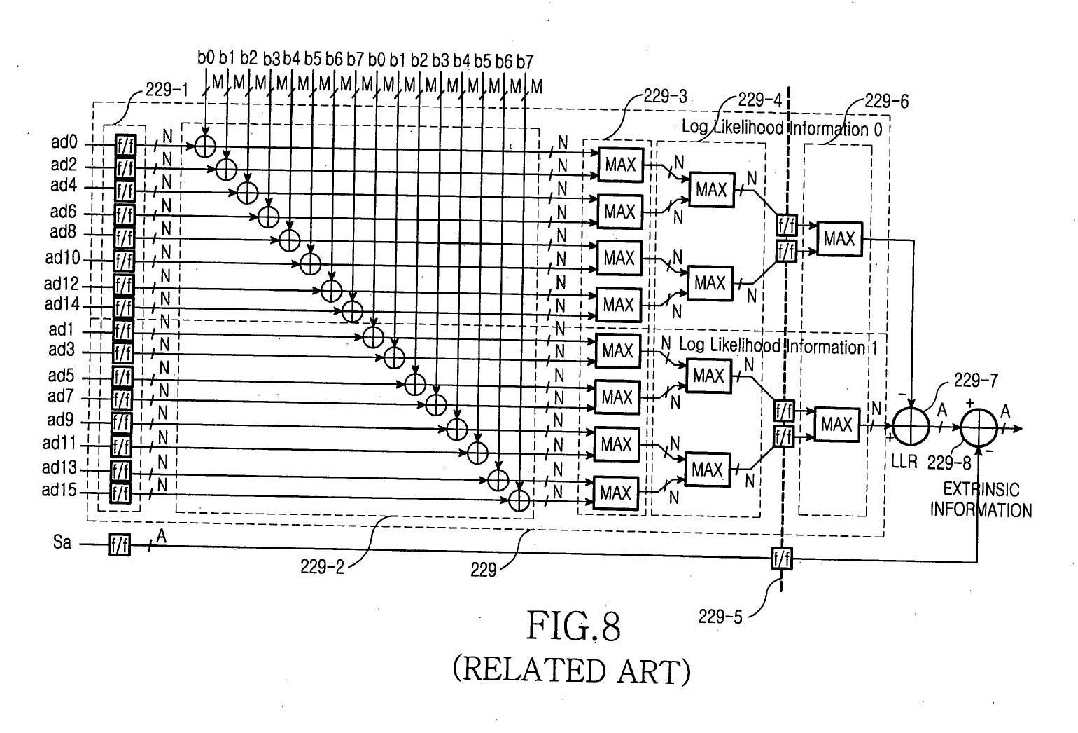

FIG. 8 is a diagram illustrating a detailed structure of a general LLR block. Referring to FIG. 8, a memory buffer 229-1 comprises flip-flops for receiving and storing alpha input values ad0 to ad15 calculated by the alpha metric block 225. A calculation block 229-2 performs XOR operations on alpha metric input values ad0 to ad15 output from the memory buffer 229-1 and beta metric values b0 to b7 provided from the beta metric block 227. A maximum value calculation block 229-3 compares the XOR result values in pairs to select greater values. A maximum value calculation block 229-4 compares the selected values output from the maximum value calculation block 229-3 in pairs to select greater values. A flip-flop block 229-5, which is a pipeline, stores the selected values output from the maximum value calculation block 229-4. Herein, the pipeline is a memory for memorizing previous state values. For example, in the process of calculating a k^{th} state, because the pipeline 229-5 is maintaining a (k−1)^{th} state value, the LLR block 229 is not required to wait until the (k−1)^{th} state value to calculate the k^{th} state value, contributing to an increase in calculation speed.

A maximum value calculation block 229-6 compares the values output from the pipeline 229-5 in pairs to select greater values, and a LLR calculator 229-7 performs a LLR algorithm on the two values output from the maximum value calculation block 229-6. An error corrector 229-8 receives an output value of the LLR calculator 229-7 and an input signal Sₐ, and outputs error correction information (or extrinsic information). The LLR algorithm and the error correction information are not related to the present invention, a description, therefore, will be omitted. Unlike the alpha and beta metric blocks 225 and 227, the LLR block 229 does not have the recursive structure. Therefore, it is possible to design a circuit, which is fast enough, by applying a multi-stage pipeline structure.

A first embodiment of the present invention replaces normalization of the general alpha and delta blocks with bit normalization, and accordingly, extends the pipeline in the LLR block.

An alternative embodiment of the present invention replaces normalization of alpha and beta metrics with normalization of delta metrics, thereby reducing a delay in alpha and beta metric calculation.

The first embodiment of the present invention will be described in detail herein below.

Normalization in the turbo decoder is used to prevent the occurrence of overflow and underflow in which calculated metric values are mismatched with a bit width representing the metrics. The overflow and underflow change a sign of symbols, affecting decoding performance. In order to prevent the overflow and underflow of signals, the first embodiment uses a method of detecting the overflow and underflow by searching for the maximum value or the minimum value among the metric values and subtracting or adding a predetermined value from/to the remaining metric values.

The first embodiment of the present invention uses bit normalization as a normalization method for preventing the overflow and underflow. The bit normalization sufficiently widens the bit width representing the metrics and monitors the most significant bit (MSB) of each of the metrics.

Because a constraint length of the convolutional code is finite and thus an interval where one state value affects another state value in a trellis also has the distance corresponding to the constraint length, a difference between the maximum value and the minimum value for each of the metrics does not increase infinitely. Therefore, the bit normalization is performed on the overflow or underflow metric where all the metrics exceed a predetermined boundary in a binary domain. Specifically, if an overflow or underflow metric is discovered, the bit normalization reverses the MSB bit of size bits except a sign bit of the overflow or underflow, thereby automatically performing the normalization.

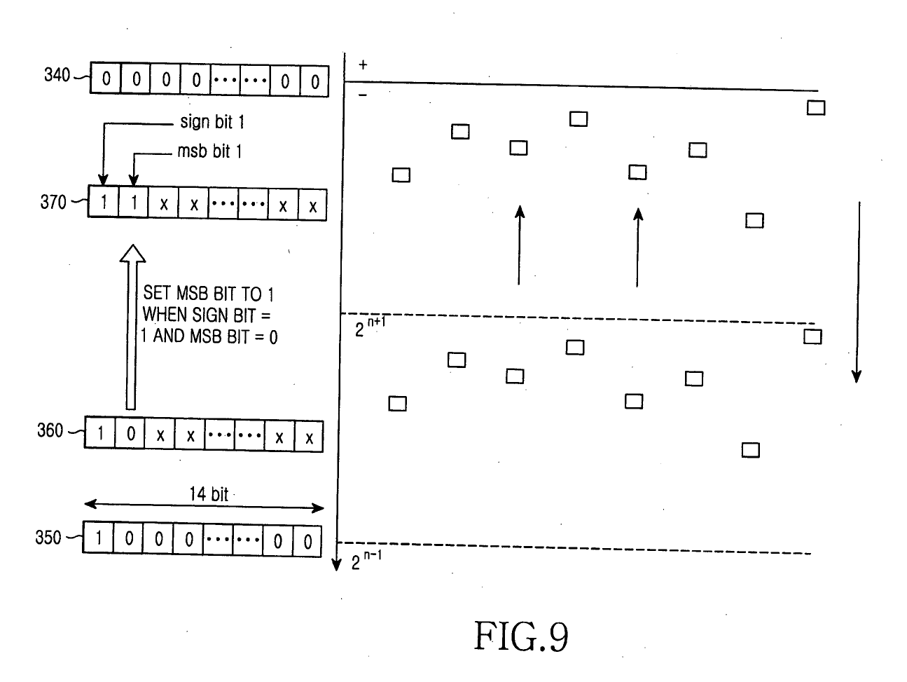

FIG. 9 is a diagram illustrating bit normalization in the case of underflow according to an embodiment of the present invention. Shown in FIG. 9 are metrics expressed with 14 size bits including a sign bit, having a predetermined bit width of 128 to −128. A metric 340 in which all bits including a sign bit are 0 is a code boundary of the bit width, and a metric 350 in which a sign bit is 1 and the remaining size bits are all 0 is an underflow boundary. A particular metric 360 whose MSB is 0 becomes an underflow metric. Therefore, the bit normalization is performed on the underflow metric 360 by reversing the MSB bit thereof. Then the bit normalization-processed metric 370 generated by reversing the MSB bit of the underflow metric 360 to ‘1’ is distributed within the bit width.

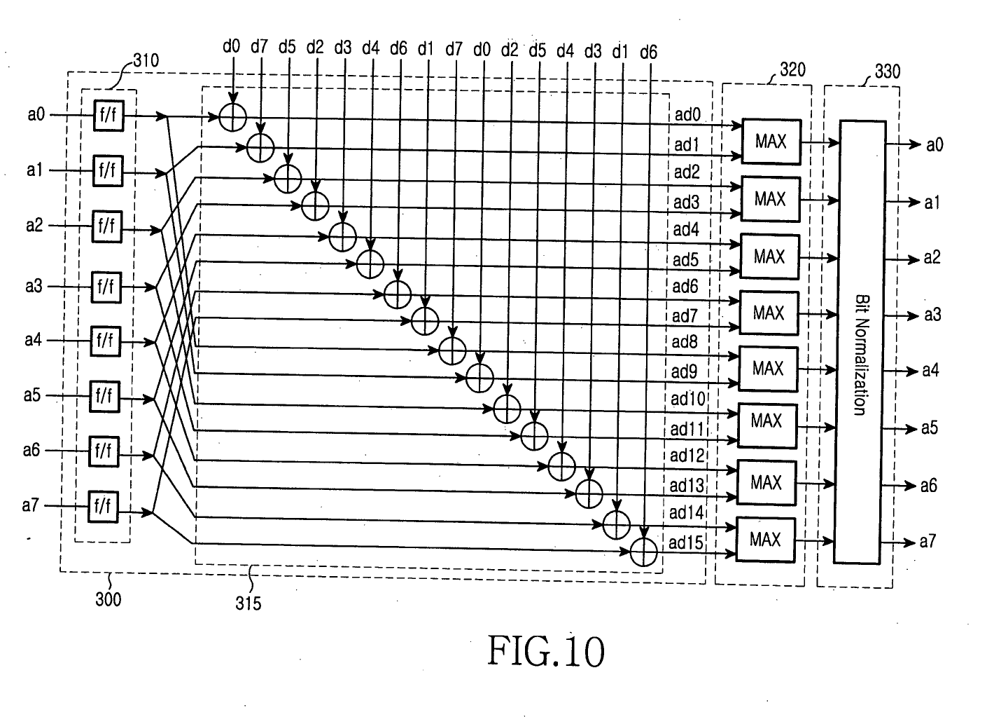

FIG. 10 is a diagram illustrating a detailed structure of an alpha metric calculation block to which bit normalization is applied according to an embodiment of the present invention. Referring to FIG. 10, a memory buffer 310 comprises flip-flops for receiving and storing alpha input values a0 to a7 for initial state setting. A calculation block 315 performs XOR operations on previous alpha metric input values a0 to a7 output from the flip-flops and delta metrics d0 to d7 output from a delta metric block, and outputs the XOR results to maximum value calculation blocks 320 in pairs. The maximum value calculation blocks 320 each compare the result values ad0 to ad15 of the calculation block 315 in pairs to select greater values. The selected values are output as alpha metric values through a bit normalization block 330. The output alpha metric values are used as alpha metric input values for calculating the next alpha metrics.

For example, if initial input values a0 and a1 are output from the memory buffer 310, XOR results ad0 and ad1 between the initial input values a0 and a1 and the current-state metrics d0 and d7 are input to the maximum value calculation block 320. The maximum value calculation block 320 compares the ad0 with the ad1, and selects the greater value. The selected value is normalized in the bit normalization block 330, and stored in a first flip-flop as a0. The a0 is used as an input value for calculating the next alpha metric value, and the input value a0 is logically XORed again with the d7 value. The XOR result ad8 between the a0 and the d7 is normalized again passing through the maximum value calculation block 320 and the bit normalization block 330, and output as a4. The a4 is again used as an initial alpha input value.

Like the alpha metric block, the beta metric block is also equal to the general beta metric block in metric calculation process, and the maximum value calculation results undergo bit normalization.

An LLR block with a 2-stage pipeline structure is used for the bit normalization-processed alpha and beta metric values.

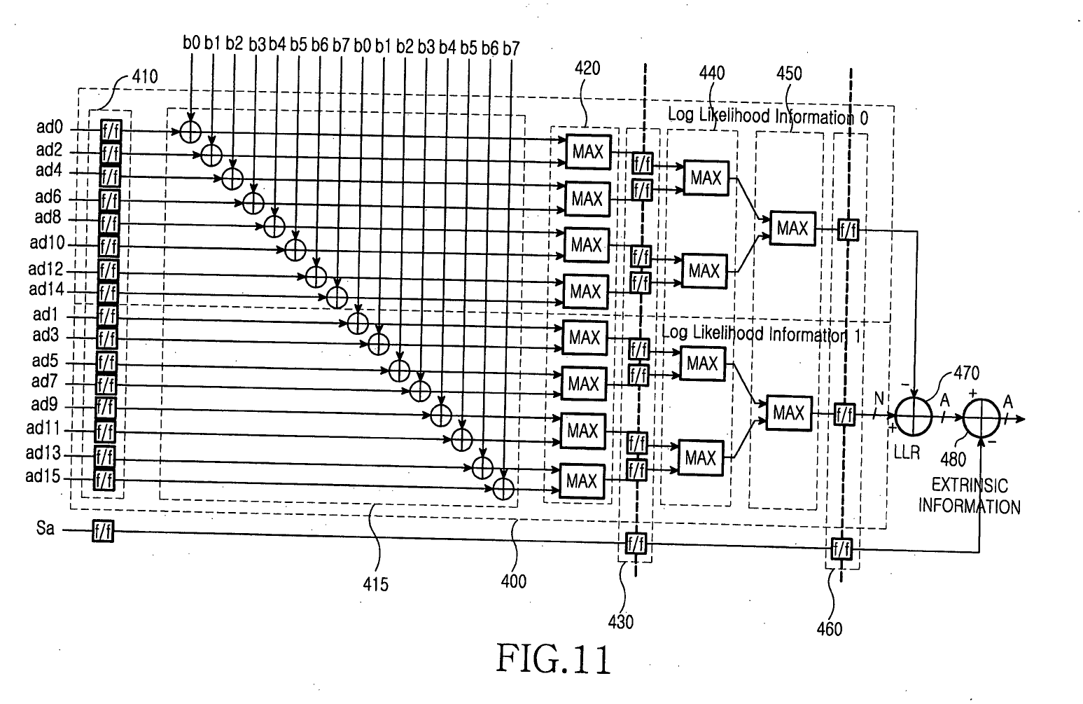

FIG. 11 is a diagram illustrating a detailed structure of an LLR block according to a first embodiment of the present invention. Referring to FIG. 11, a LLR block 400 has two pipeline stages 430 and 460 applied therein. Specifically, a memory buffer 410 comprises flip-flops for receiving and storing bit normalization-processed alpha metric values ad0 to ad 15 from an alpha metric block. A calculation block 415 performs XOR operations on alpha metric values ad0 to ad15 output from the memory buffer 410 and beta metric values b0 to b7 provided from a beta metric block. A maximum value calculation block 420 compares the XOR result values in pairs to select greater values. A pipeline 430 stores the selected values received from the maximum value calculation block 420 in their associated flip-flops thereof. A maximum value calculation block 440 compares the selected values output from the pipeline 430 in pairs to select greater values. A maximum value calculation block 450 compares the selected values output from the maximum value calculation block 440 in pairs to select greater values. A pipeline 460 stores the selected values output from the maximum value calculation block 450 in their associated flip-flops thereof, and an LLR calculator 470 performs a LLR algorithm on the result values output from the pipeline 460. An error corrector 480 receives an output value of the LLR calculator 470 and an input signal Sₐ, and outputs error correction information (or extrinsic information).

With reference to FIGS. 8 and 11, a description will now be made of a delay of the LLR block.

The LLR block 229 of FIG. 8 has the pipeline 229-5 interposed between the maximum value calculation block 229-4 and the maximum value calculation block 229-6. A delay of the LLR block 229 will be described below. In the preceding stages of the pipeline 229-5, a 3-stage adder delay occurs through the calculation block 229-2 and the two maximum value calculation blocks 229-3 and 229-4. In the following stages of the pipeline 229-5, a 3-stage adder delay occurs through the maximum value calculation block 229-6, the LLR calculator 229-7 and the error corrector 229-8.

A delay of the LLR block 400 of FIG. 11 including the pipeline 430 and the pipeline 460 will be described below. In the preceding sages of the pipeline 430, a 2-stage adder delay occurs through the calculation block 415 and the maximum value calculation block 420. In the stages between the pipeline 430 the pipeline 460, a 2-stage adder delay occurs through the two maximum value calculation blocks 440 and 450. In the following stages of the pipeline 460, a 2-stage adder delay occurs through the LLR calculator 470 and the error corrector 480. As a result, the adder delay is reduced through the addition of the pipelines.

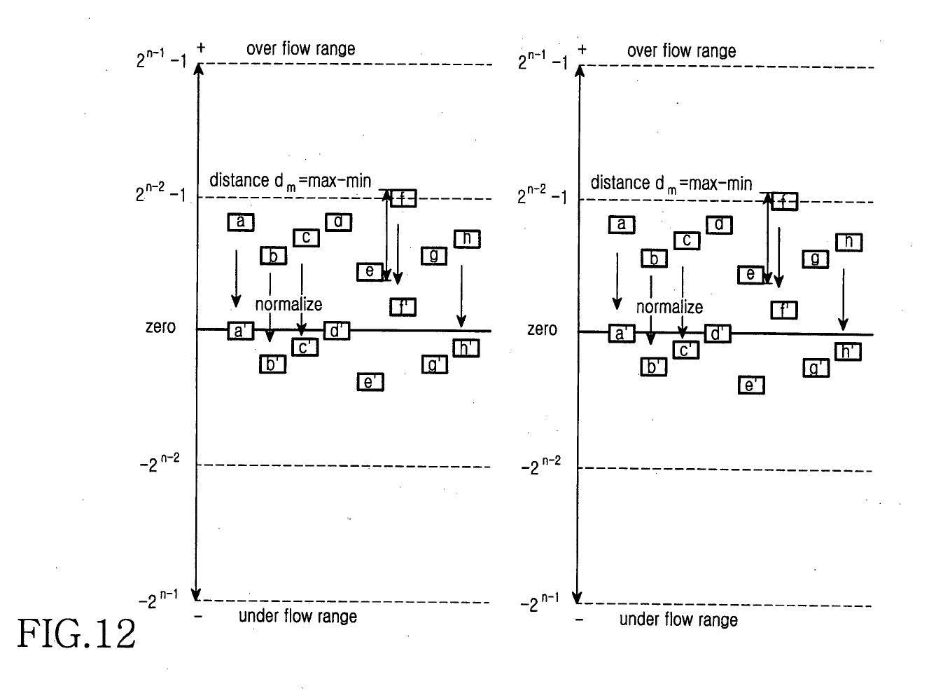

An alternative embodiment of the present invention will now be described with reference to FIGS. 12 to 14B.

In the decoding process with a SISO decoder, the meaningful factors are not the alpha and beta metric values but the difference between the metric values. Therefore, if a level of delta metrics which become input values for the alpha and beta metrics is previously controlled, overflow and underflow can be prevented in the alpha and beta metrics.

The alternative embodiment of the present invention performs normalization on the delta metrics. Because the pipeline cannot be applied to the alpha and beta metrics due to their recursive structure, the pipeline is applied to the result values obtained by performing bit normalization on the delta metrics. Specifically, the present invention uses a scheme in which if an output delta metric exceeds a predetermined range, the total level of the metrics is adjusted by subtracting or adding a predetermined value from/to the delta metric. To perform this normalization, a distance dm between the maximum value and the minimum value for each of the metrics should be finite, and during the next metric calculation, a difference between a previous or next metric and a metric to be calculated should be finite. Actually, due to the characteristic of the trellis system configuration, a maximum distance is determined for each metric and the maximum distance does not exceed a predetermined level. Therefore, the SISO decoder using the trellis structure satisfies the foregoing conditions. In addition, because the delta metrics which are input values are finite, a value obtained when calculating the next metric from the previous or next metric has a finite distance from the value obtained in the current metric calculation.

FIG. 12 is a diagram illustrating an example of a normalization operation according to an embodiment of the present invention. Referring to FIG. 12, a metric value is expressed with 2ⁿ bits, and a bit width ranges between 2ⁿ⁻¹−1 and −2ⁿ⁻¹1. The 2ⁿ⁻¹ is an overflow boundary and the −2ⁿ⁻¹ is an underflow boundary.

Previous metrics a to h and metrics a′ to h′ calculated from the previous metrics a to h are distributed, exhibiting finite distances therebetween. That is, a maximum distance dm of each metric is finite. When the next metric is calculated from the previous metric value, it is determined whether a particular metric value exceeds 2ⁿ⁻² If it is determined that there are metric values exceeding 2ⁿ⁻², the normalization is performed by subtracting a predetermined value from the metric values exceeding 2ⁿ⁻². In this manner, it is possible to previously decrease a level of the metric values before the metric values approach the overflow range. Likewise, the total level of the metrics is adjusted within a predetermined range by previously increasing a level of metric values before the metric values approach the underflow range.

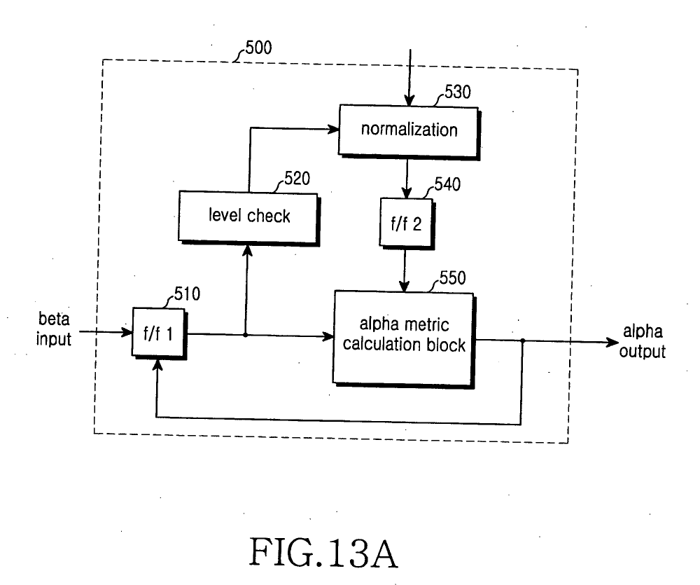

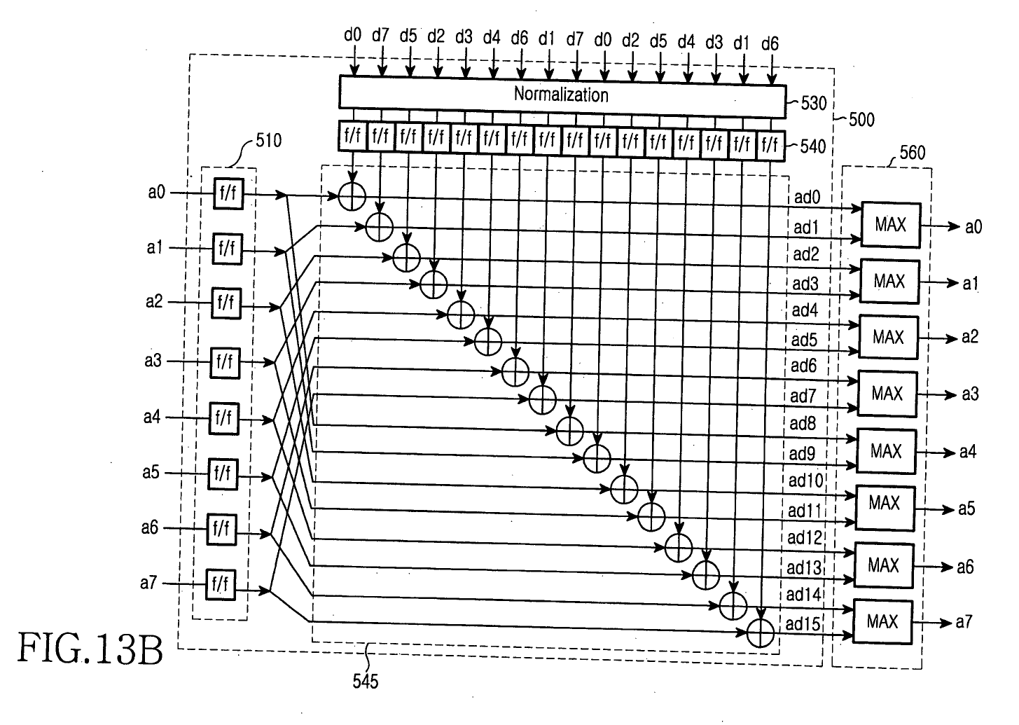

FIG. 13A is a diagram illustrating a structure of an alpha metric block according to an embodiment of the present invention. Referring to FIG. 13A, an alpha metric block 500 comprises a first memory buffer 510 for receiving and storing alpha input values, a level check block 520 for checking a level of a previous metric every clock cycle, a normalization block 530 for performing bit normalization on delta metrics according to the result of the level check block 520, a second memory buffer 540 for storing the delta metric values normalized by the normalization block 530, and an alpha metric calculation block 550 for calculating alpha metric values using the normalized delta metric values output from the second memory buffer 540 and the alpha metric input values output from the first memory buffer 510.

FIG. 13B is a diagram illustrating a detailed structure of an alpha metric calculation block according to an embodiment of the present invention. Referring to FIG. 13B, a first memory buffer 510 comprises flip-flops for receiving and storing alpha input values a0 to a7. A normalization block 530 performs normalization on delta metrics d0 to d7 received from a delta metric block according to a level of previous-state metrics, checked by a level check block 520, and stores the normalized delta metrics in a second memory buffer 540. A calculation block 545 performs XOR operations on the normalized delta metrics d0 to d7 output from the second memory buffer 540 and the input alpha metrics a0 to a7, and outputs the XOR results to a maximum value calculation block 560. The maximum value calculation block 560 compares the result values ad0 to ad15 of the calculation block 545 in pairs to select greater values. The selected values a0 to a7 are output as alpha metric values used for calculating the next alpha metric values. For example, when an input alpha metric a1 is calculated, the level check block 520 checks a level of a previous metric value a0. If it is determined that the level of the a0 exceeds a predetermined bit width, the normalization block 530 subtracts a predetermined value from d7 to adjust a level of the d7, and outputs the level-adjusted value. Then the calculation block 545 performs XOR operations on the a1 and the bit normalization-processed d7, and outputs the result value ad1. The maximum value calculation block 560 compares the ad1 with an XOR result ad0 between the a0 and the d0, and outputs a greater value a0.

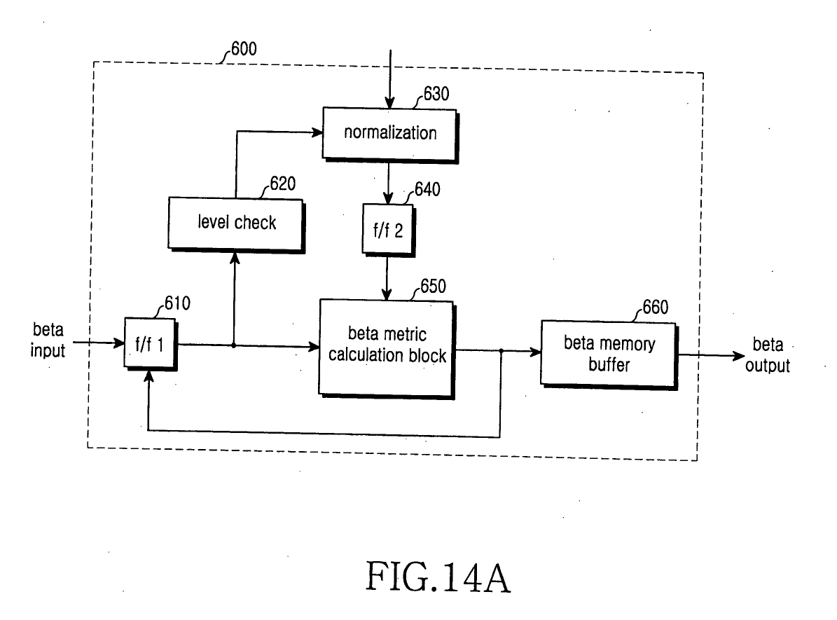

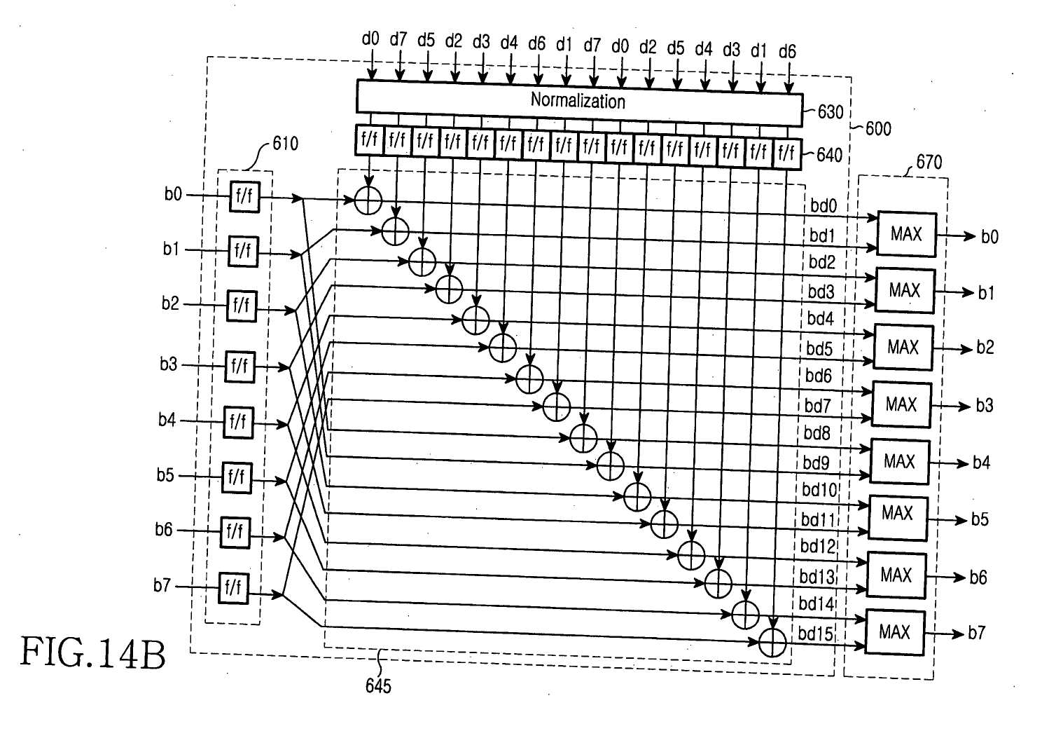

FIG. 14A is a diagram illustrating a structure of a beta metric block according to an embodiment of the present invention. Referring to FIG. 14A, a beta metric block 600 comprises a first memory buffer 610, a level check block 620, a normalization block 630, a second memory buffer 640, a beta metric calculation block 650, and a beta memory buffer 660. The beta memory buffer 660 stores beta metric values output from the beta metric calculation block 650 and outputs the beta metric values in the reverse order, to calculate a previous beta metric using the current beta metric according to the beta metric calculation characteristic.

Because the elements 610 to 650 of the beta metric block 600 are equal in operation to the corresponding elements of the alpha metric block 500, a detailed description thereof will be omitted.

FIG. 14B is a diagram illustrating a detailed structure of a beta metric calculation block according to an embodiment of the present invention. Referring to FIG. 14B, a first memory buffer 610 comprises flip-flops for receiving and storing beta input values b0 to b7. A normalization block 630 performs normalization on delta metrics d0 to d7 output from a delta metric block according to a level of a previous metric, checked by a level check block 620, and stores the result values in a second memory buffer 640. A calculation block 645 performs XOR operations on the bit normalization-processed delta metrics d0 to d7 output from the flip-flops in the second memory buffer 640 and the input beta metrics b0 to b7, and outputs the XOR results to a maximum value calculation block 670. The maximum value calculation block 670 compares the result values ad0 to ad15 of the calculation block 645 in pairs to select greater values b0 to b7. The selected values b0 to b7 are input back to the first memory buffer 610 as beta metric values used for calculating the next beta metric values.

For example, when an input beta metric b0 is calculated, the level check block 620 checks a level of a next metric value b1. If it is determined that the level of the b1 exceeds a predetermined bit width, the normalization block 630 subtracts or adds a predetermined value from/to d0 to adjust a level of the d0, and outputs the level-adjusted value. Then the calculation block 645 performs XOR operations on the b0 and the bit normalization-processed d0, and outputs the result value bd0. The maximum value calculation block 670 compares the bd0 with an XOR result bd1 between the b1 and the d7, and outputs a greater value b0.

The second memory buffers 540 and 640, i.e., pipelines, for storing normalized delta metric values are applied to the alpha and beta metric blocks 500 and 600, respectively. As a result, each of delays of the alpha and beta metric blocks 500 and 600 becomes {adder+comparator+MUX+flip-flop} which is shorter by a delay of the normalization block than each of the delays {adder+comparator+MUX+normalization+flip-flop} of the general alpha and beta metric blocks 225 and 227.

As can be understood from the foregoing description, a decoding speed of a turbo decoder is increased by modifying a structure of the normalization block for calculation of alpha and beta metrics in the turbo decoder for the general decoding apparatus. The increase in decoding speed of the novel decoding apparatus contributes to performance improvement of the decoding apparatus. The novel decoding apparatus meets user demands for high speed in the high-speed mobile communication system such as the 1×EV-DV system and the UMTS system.

While the invention has been shown and described with reference to certain embodiments thereof, it will be understood by those skilled in the art that various changes in form and details may be made therein without departing from the spirit and scope of the invention as defined by the appended claims.

1. A turbo decoding apparatus for decoding using a trellis structure comprised of a plurality of states and paths between the states in a high-speed packet data communication system, the apparatus comprising:
a plurality of delta metric blocks for calculating a delta metric indicating a transition probability for paths from each state to another state according to an input data bit;
an alpha metric block for normalizing the delta metric, and calculating an alpha metric for indicating a forward state transition probability for each of the states using the normalized delta metric;
at least one beta metric block for normalizing the delta metric, and calculating a beta metric for indicating a reverse state transition probability for each of the states using the normalized delta metric; and
a log likelihood ratio (LLR) block for receiving the alpha metric and the beta metric and calculating LLR values for symbols of a final state using the received alpha metric and beta metric.

2. The turbo decoding apparatus of claim 1, wherein the alpha metric block comprises:
a first buffer comprising flip-flops for receiving initial state values or previous alpha metric values and storing the received values as alpha input values;
a level check block for checking a level of the previous alpha metric values every clock cycle;
a normalization block for receiving the delta metrics and normalizing the delta metrics according to the checked level;
a second buffer for storing the normalized delta metric values; and
an alpha metric calculation block for calculating a current alpha metric value using the normalized delta metric values and alpha input values received from the first buffer.

3. The turbo decoding apparatus of claim 2, wherein the normalization block performs normalization by subtracting or adding a predetermined value from/to the delta metric values, if overflow or underflow occurs in which any one of the previous alpha metric values exceeds a predetermined bit width.

4. The turbo decoding apparatus of claim 2, wherein the alpha metric calculation block comprises:
a calculation block for performing exclusive-OR (XOR) operations on the normalized delta metric values and the previous alpha metric values; and
a maximum value calculation block for comparing output values of the calculation block in pairs to select greater values.

5. The turbo decoding apparatus of claim 1, wherein the beta metric block comprises:
a first buffer comprising flip-flops for receiving initial state values or previous beta metric values and storing the received values as beta input values;
a level check block for checking a level of the previous beta metric values every clock cycle;
a normalization block for receiving the delta metrics and normalizing the delta metrics according to the checked level;
a second buffer for storing the normalized delta metric values;
a beta metric calculation block for calculating a current beta metric value using the normalized delta metric values and beta input values received from the first buffer; and
a third buffer for storing beta metric values output from the beta metric calculation block and outputting the beta metric values in a reverse order.

6. The turbo decoding apparatus of claim 5, wherein the normalization block performs normalization by subtracting or adding a predetermined value from/to the delta metric values, if overflow or underflow occurs in which any one of the previous alpha metric values exceeds a predetermined bit width.

7. The turbo decoding apparatus of claim 5, wherein the beta metric calculation block comprises:
a calculation block for performing XOR operations on the normalized delta metric values and the previous beta metric values; and
a maximum value calculation block for comparing output values of the calculation block in pairs to select greater values.

8. A turbo decoding apparatus for decoding using a trellis structure comprised of a plurality of states and paths between the states in a high-speed packet data communication system, the apparatus comprising:
a plurality of delta metric blocks for calculating a delta metric indicating a transition probability for paths from each state to another state according to an input data bit;
an alpha metric block for calculating an alpha metric by receiving the delta metric, and performing bit normalization by reversing a most significant bit (MBS) excluding a sign bit of the alpha metric if the alpha metric values exceed a predetermined bit width;
a beta metric block for calculating a beta metric by receiving the delta metric, and performing bit normalization by reversing an MBS bit excluding a sign bit of the beta metric if the beta metric values exceed a predetermined bit width; and
a log likelihood ratio (LLR) block comprising two buffers for receiving the bit-normalized alpha and beta metric values and storing intermediate calculation values for calculating LLR values for symbols of a final state.

9. The turbo decoding apparatus of claim 8, wherein the LLR block comprises:
flip-flops for storing the bit-normalized alpha metric values received from the alpha metric block;
a calculation block for performing exclusive-OR (XOR) operations on alpha metric values received from the flip-flops and the bit-normalized beta metric values from the beta metric block;
a first maximum value calculation block for comparing the XOR result values in pairs to select greater values;
a first buffer comprising flip-flops for storing the selected values received from the first maximum value calculation block;
a second maximum value calculation block for comparing the selected values received from the first buffer in pairs to select greater values;
a third maximum value calculation block for comparing the selected values received from the second maximum value calculation blocks in pairs to select grater values;
a second buffer comprising flip-flops for storing the selected values output from the third maximum value calculation block;
a LLR calculator for calculating an LLR value by performing a LLR algorithm on the result values output from the second buffer; and
an error corrector for performing error correction on the LLR value.

10. The turbo decoding apparatus of claim 8, wherein the alpha metric block comprises:
a buffer comprising flip-flops for receiving initial state values or previous alpha metric values and storing the received values as alpha input values;
a calculation block for performing XOR operations on the alpha metric input values and the delta metric values;
a maximum value calculation block for comparing the XOR result values in pairs to select greater values; and
a bit normalization block for performing bit normalization on each of the selected values.

11. The turbo decoding apparatus of claim 8, wherein the beta metric block comprises:
a buffer comprising flip-flops for receiving initial state values or previous beta metric values and storing the received values as beta input values;
a calculation block for performing XOR operations on the beta metric input values and the delta metric values;
a maximum value calculation block for comparing the XOR result values in pairs to select greater values; and
a bit normalization block for performing bit normalization on each of the selected values.

12. A method for decoding using a trellis structure, comprising the steps of:
calculating a delta metric indicating a transition probability for paths from each state to another state according to an input data bit;
normalizing the delta metric, and calculating an alpha metric for indicating a forward state transition probability for each of the states using the normalized delta metric;
normalizing the delta metric, and calculating a beta metric for indicating a reverse state transition probability for each of the states using the normalized delta metric; and
receiving the alpha metric and the beta metric and calculating log likelihood ratio (LLR) values for symbols of a final state using the received alpha metric and beta metric.

13. The method of claim 12, wherein the step of calculating a delta metric further comprises the steps of:
receiving initial state values or previous alpha metric values and storing the received values as alpha input values;
checking a level of the previous alpha metric values every clock cycle;
receiving the delta metrics and normalizing the delta metrics according to the checked level;
storing the normalized delta metric values; and
calculating a current alpha metric value using the normalized delta metric values and alpha input values received from a first buffer.

14. The method of claim 13, wherein the step of checking a level further comprise:
subtracting or adding a predetermined value from/to the delta metric values, if overflow or underflow occurs in which any one of the previous alpha metric values exceeds a predetermined bit width.

15. The method of claim 13, wherein the step of calculating a current alpha metric value further comprises:
performing exclusive-OR (XOR) operations on the normalized delta metric values and the previous alpha metric values; and
comparing output values of a calculation block in pairs to select greater values.

16. The method of claim 12, wherein the step of normalizing the delta metric, and calculating a beta metric further comprises:
receiving initial state values or previous beta metric values and storing the received values as beta input values;
checking a level of the previous beta metric values every clock cycle;
receiving the delta metrics and normalizing the delta metrics according to the checked level;
storing the normalized delta metric values;
calculating a current beta metric value using the normalized delta metric values and beta input values received from a first buffer; and
storing beta metric values output from a beta metric calculation block and outputting the beta metric values in a reverse order.

17. The method of claim 16, wherein the step of receiving the delta metrics and normalizing the delta metrics further comprises:
subtracting or adding a predetermined value from/to the delta metric values, if overflow or underflow occurs in which any one of the previous alpha metric values exceeds a predetermined bit width.

18. The method of claim 16, wherein the step of calculating a current beta metric value further comprises:
performing XOR operations on the normalized delta metric values and the previous beta metric values; and
comparing output values of a calculation block in pairs to select greater values.
